(19) United States
(12) Patent Application Publication
(10) Pub. No.: US 2023/0320217 A1
(43) Pub. Date: Oct. 5, 2023

(54) PIEZOELECTRIC-BODY FILM JOINT SUBSTRATE AND MANUFACTURING METHOD THEREOF

(71) Applicant: Oki Electric Industry Co., Ltd., Tokyo (JP)

(72) Inventors: Hironori FURUTA, Tokyo (JP); Toru KOSAKA, Tokyo (JP); Takahito SUZUKI, Tokyo (JP); Kenichi TANIGAWA, Tokyo (JP); Takuma ISHIKAWA, Tokyo (JP); Yutaka KITAJIMA, Tokyo (JP)

(73) Assignee: Oki Electric Industry Co., Ltd., Tokyo (JP)

(21) Appl. No.: 18/181,093

(22) Filed: Mar. 9, 2023

(30) Foreign Application Priority Data
Mar. 30, 2022 (JP) 2022-055593

(51) Int. Cl. H10N 30/073; H10N 30/00; H10N 30/06

(52) U.S. Cl. CPC H10N 30/073; H10N 30/10516; H10N 30/06

(57) ABSTRACT

A piezoelectric-body film joint substrate includes a substrate, a substrate electrode provided on the substrate, a first piezoelectric-body film stuck on the substrate electrode and including a first piezoelectric film and a first upper electrode film formed on the first piezoelectric film, and a second piezoelectric-body film stuck on the first upper electrode film and including a second piezoelectric film different from the first piezoelectric film and a second upper electrode film formed on the second piezoelectric film.

### BACKGROUND OF THE INVENTION

### 1. Field of the Invention

The present disclosure relates to a piezoelectric-body film joint substrate and a manufacturing method thereof.

### 2. DESCRIPTION OF THE RELATED ART

Conventionally, there has been proposed a device formed by stacking a plurality of piezoelectric films of different types. See Japanese Patent Application Publication No. 2018-190890 (Patent Reference 1), for example.

However, a high-performance device including a plurality of piezoelectric films cannot be obtained when a plurality of piezoelectric films of different types are stacked on the same substrate in a conventional device.

### SUMMARY OF THE INVENTION

An object of the present disclosure is to provide a high-performance piezoelectric-body film joint substrate in which piezoelectric films of two or more types are provided in superimposition with each other on the same substrate and a manufacturing method thereof.

A piezoelectric-body film joint substrate in the present disclosure includes a substrate, a substrate electrode provided on the substrate, a first piezoelectric-body film stuck on the substrate electrode and including a first piezoelectric film and a first upper electrode film formed on the first piezoelectric film, and a second piezoelectric-body film stuck on the first upper electrode film and including a second piezoelectric film different from the first piezoelectric film and a second upper electrode film formed on the second piezoelectric film.

A method of manufacturing a piezoelectric-body film joint substrate in the present disclosure includes peeling off a first piezoelectric-body film formed on a first substrate and including a first piezoelectric film and a first electrode film provided on the first piezoelectric film and a second piezoelectric-body film formed on a second substrate and including a second piezoelectric film and a second electrode film provided on the second piezoelectric film respectively from the first substrate and the second substrate, sticking the first piezoelectric-body film on an electrode formed on a third substrate different from both of the first substrate and the second substrate, and sticking the second piezoelectric-body film on the first piezoelectric-body film.

According to the present disclosure, it is possible to provide a high-performance piezoelectric-body film joint substrate in which piezoelectric films of two or more types are provided in superimposition with each other on the same substrate and a manufacturing method thereof.

### BRIEF DESCRIPTION OF THE DRAWINGS

The present disclosure will become more fully understood from the detailed description given hereinbelow and the accompanying drawings which are given by way of illustration only, and wherein:

FIG. 1 is a side view schematically showing the structure of a piezoelectric-body film joint substrate according to a first embodiment;

FIG. 2 is a top view schematically showing the structure of the piezoelectric-body film joint substrate in FIG. 1;

FIG. 3 is a cross-sectional view of the piezoelectric-body film joint substrate in FIG. 2 taken along the line S3-S3;

FIG. 4 is a flowchart showing a method of manufacturing the piezoelectric-body film joint substrate according to the first embodiment;

FIGS. 5A and 5B are a top view and a cross-sectional view schematically showing the structure of a PZT epitaxial growth film in step ST101 in FIG. 4, and FIGS. 5C and 5D are a top view and a cross-sectional view schematically showing the structure of the PZT epitaxial growth film in step ST102 in FIG. 4;

FIGS. 6A and 6B are a top view and a cross-sectional view schematically showing the structure of an AIN epitaxial growth film in step ST104 in FIG. 4, and FIGS. 6C and 6D are a top view and a cross-sectional view schematically showing the structure of the AIN epitaxial growth film in step ST105 in FIG. 4;

FIGS. 7A and 7B are cross-sectional views schematically showing a holding process of a plurality of PZT piezoelectric-body films in step ST103 in FIG. 4;

FIGS. 8A and 8B are cross-sectional views schematically showing a holding process of a plurality of AIN piezoelectric-body films in step ST106 in FIG. 4;

FIG. 9A is a cross-sectional view schematically showing a sticking process of the AIN piezoelectric-body film in step ST107 in FIG. 4, and FIG. 9B is a top view showing a state in which the AIN piezoelectric-body film has been stuck;

FIG. 10A is a cross-sectional view schematically showing a sticking process of the PZT piezoelectric-body film in step ST108 in FIG. 4, and FIG. 10B is a top view showing a state in which the PZT piezoelectric-body film has been stuck;

FIG. 11A is a cross-sectional view showing a manufacturing process of the next piezoelectric-body film joint substrate, and FIG. 11B is a top view showing a state in which the PZT piezoelectric-body film has been stuck;

FIGS. 12A and 12B are a side view and a top view schematically showing the structure of a piezoelectric-body film joint substrate according to a modification of the first embodiment;

FIGS. 13A and 13B are a side view and a top view schematically showing the structure of a piezoelectric-body film joint substrate according to a second embodiment;

FIG. 14 is a cross-sectional view schematically showing the structure of an epitaxial growth film including a PZT piezoelectric-body film;

FIG. 15 is a cross-sectional view schematically showing the structure of an epitaxial growth film including an AIN piezoelectric-body film;

FIG. 16 is a flowchart showing a method of manufacturing the piezoelectric-body film joint substrate in FIGS. 13A and 13B;

FIGS. 17A and 17B are a top view and a cross-sectional view schematically showing the structure of a PZT epitaxial growth film in step ST201 in FIG. 16, and FIGS. 17C and 17D are a top view and a cross-sectional view schematically showing the structure of the PZT epitaxial growth film in step ST202 in FIG. 16;

FIGS. 18A and 18B are a top view and a cross-sectional view schematically showing the structure of an AIN epitaxial growth film in step ST204 in FIG. 16, and FIGS. 18C and 18D are a top view and a cross-sectional view schematically showing the structure of the AIN epitaxial growth film in step ST205 in FIG. 16;

FIGS. 19A and 19B are cross-sectional views schematically showing a holding process of a plurality of PZT piezoelectric-body films in step ST203 in FIG. 16;

FIGS. 20A and 20B are cross-sectional views schematically showing a holding process of a plurality of AIN piezoelectric-body films in step ST206 in FIG. 16;

FIG. 21A is a cross-sectional view schematically showing a sticking process of the AIN piezoelectric-body film in step ST207 in FIG. 16, and FIG. 21B is a top view showing a state in which the AIN piezoelectric-body film has been stuck;

FIG. 22A is a cross-sectional view schematically showing a sticking process of the PZT piezoelectric-body film in step ST208 in FIG. 16, and FIG. 22B is a top view showing a state in which the PZT piezoelectric-body film has been stuck; and

FIG. 23A is a cross-sectional view showing a manufacturing process of the next piezoelectric-body film joint substrate, and FIG. 23B is a top view showing a state in which the PZT piezoelectric-body film has been stuck.

### DETAILED DESCRIPTION OF THE INVENTION

A piezoelectric-body film joint substrate and a manufacturing method thereof according to each embodiment will be described below with reference to the drawings. The following embodiments are just examples and a variety of modifications are possible within the scope of the present disclosure. In the present application, the piezoelectric-body film joint substrate is a product as an intermediate in which a plurality of piezoelectric films are provided on the same substrate. While the piezoelectric films are desired to be monocrystalline piezoelectric films, it is also possible to form the piezoelectric-body film joint substrate with polycrystalline piezoelectric films.

By using a piezoelectric-body film joint substrate according to each embodiment, a piezoelectric film integrated device including a plurality of piezoelectric bodies can be manufactured. The piezoelectric film integrated device is an acoustic oscillation sensor, for example. Incidentally, the acoustic oscillation sensor is a sensor that detects status (e.g., distance, shape, movement or the like) of a detection target object by outputting an acoustic oscillatory wave and detecting reflected waves of the acoustic oscillatory wave. The acoustic oscillation sensor is referred to also as an “ultrasonic sensor”. In general, and in the present application, the acoustic oscillatory wave is made up of at least one of a sonic wave and an ultrasonic wave. Namely, the acoustic oscillatory wave includes a sonic wave, an ultrasonic wave, or both of a sonic wave and an ultrasonic wave.

### (1) First Embodiment

### (1-1) Structure of Piezoelectric-Body Film Joint Substrate 100

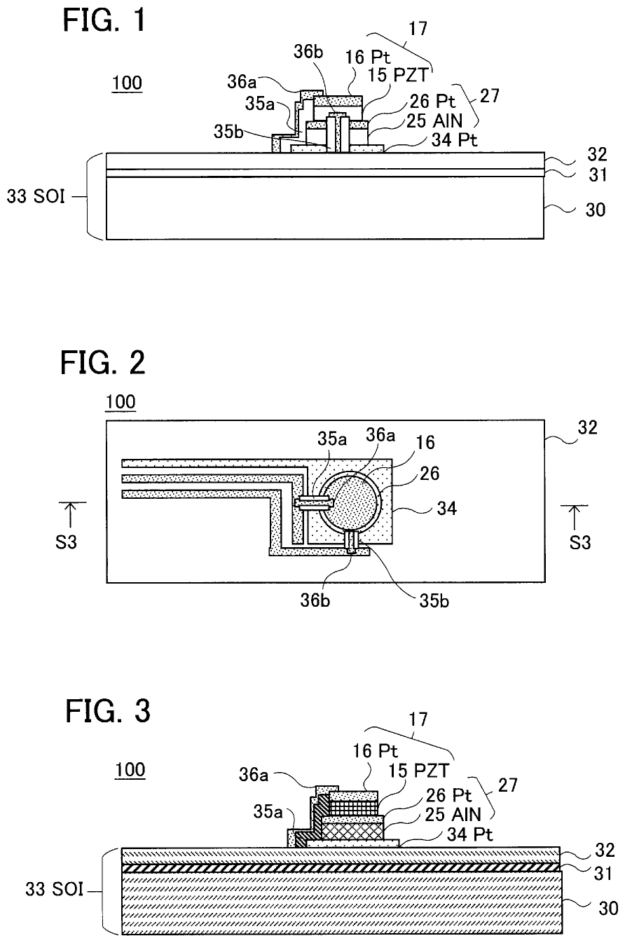

FIG. 1 is a side view schematically showing the structure of a piezoelectric-body film joint substrate 100 according to a first embodiment. FIG. 2 is a top view schematically showing the structure of the piezoelectric-body film joint substrate 100. FIG. 3 is a cross-sectional view of the piezoelectric-body film joint substrate 100 in FIG. 2 taken along the line S3-S3.

The piezoelectric-body film joint substrate 100 includes an SOI substrate 33 as a substrate and a platinum (Pt) film 34 as an electrode (i.e., substrate electrode) provided on the SOI substrate 33. As shown in FIG. 2, the Pt film 34 is connected to a wiring layer formed on the SOI substrate 33. The SOI stands for Silicon On Insulator. Further, in the SOI substrate 33, there may be formed a drive circuit for driving the piezoelectric-body film joint substrate 100 and thereby generating the acoustic oscillatory wave, a processing circuit that executes a process by using an acoustic oscillatory wave detection signal, and so forth.

The piezoelectric-body film joint substrate 100 includes an AIN piezoelectric-body film 27 as a first piezoelectric-body film stuck (i.e., bonded) on the Pt film 34 being the substrate electrode and a PZT piezoelectric-body film 17 as a second piezoelectric-body film stuck (i.e., bonded) on the AIN piezoelectric-body film 27. The AIN piezoelectric-body film 27 includes an AIN film 25 as a first piezoelectric film and a Pt film 26 as a first upper electrode film formed on the AIN film 25. The PZT piezoelectric-body film 17 includes a PZT film 15 as a second piezoelectric film different from the first piezoelectric film (e.g., in crystal structure) and a Pt film 16 as a second upper electrode film formed on the PZT film 15, and is stuck on the Pt film 26. Further, area of the PZT piezoelectric-body film 17 and area of the AIN piezoelectric-body film 27 differ from each other. In the first embodiment, the area of the PZT piezoelectric-body film 17 is smaller than the area of the AIN piezoelectric-body film 27.

The AIN represents aluminum nitride. The PZT represents piezoelectric zirconate titanate (lead zirconate titanate). As the first piezoelectric-body film, instead of the AIN piezoelectric-body film, a different piezoelectric film such as a lithium tantalate (LiTaO₃) piezoelectric-body film or a lithium niobate (LiNbO₃) piezoelectric-body film may be used. As the second piezoelectric-body film, instead of the PZT piezoelectric-body film, a different piezoelectric-body film such as a potassium sodium niobate (KNN) piezoelectric-body film or a barium titanate (BaTiO₃) piezoelectric-body film may be used. Further, while the first and second piezoelectric-body films are desired to be monocrystalline piezoelectric-body films, polycrystalline piezoelectric-body films may also be used. In the illustrated example, the first piezoelectric-body film is a piezoelectric body that detects the acoustic oscillatory wave (or its reflected waves), and is a piezoelectric body having lower specific inductive capacity and higher detection sensitivity compared to the second piezoelectric-body film. The second piezoelectric-body film is a piezoelectric body that generates the acoustic oscillatory wave, and is desired to be a piezoelectric body having a higher piezoelectric constant and capable of obtaining greater oscillation amplitude compared to the first piezoelectric-body film.

Incidentally, it is permissible even if the first piezoelectric-body film as a piezoelectric-body film on a lower side includes a PZT film and a Pt film and the second piezoelectric-body film as a piezoelectric-body film on an upper side includes an AIN film and a Pt film overlaid on the AIN film.

Further, as shown in FIG. 1, the piezoelectric-body film joint substrate 100 includes an insulation film 35a, a wiring film 36a formed on the insulation film 35a, an insulation film 35b, and a wiring film 36b formed on the insulation film 35b.

The SOI substrate 33 includes a Si substrate 30, a silicon dioxide (SiO₂) part 31 as an insulation film, and a monocrystalline silicon (monocrystalline Si) part 32. A cavity (hole) may be formed by etching the Si substrate 30 in a region of the monocrystalline Si part 32 under the PZT film 15 and the AIN film 25 (i.e., region overlapping with the piezoelectric films). The SiO₂ part 31 and the monocrystalline Si part 32 situated in the region where the cavity is formed have a function as a vibrating plate. Further, as the substrate, a substrate made of a different material such as a glass substrate or an organic film substrate may also be used instead of the SOI substrate 33. The acoustic oscillatory wave generated by the PZT film 15 is outputted through the cavity, and the AIN film 25 detects reflected waves of the acoustic oscillatory wave through the cavity.

The thickness of the PZT film 15 is generally in a range of 10 nm to 10 μm, and preferably in a range of 100 nm to 5 μm. The thickness of the AIN film 25 is generally in a range of 10 nm to 10 μm, and preferably in a range of 100 nm to 2 μm. The Pt film 34 is formed on the upper surface of the SOI substrate 33. The surface (upper surface) of the Pt film 34 and the AIN piezoelectric-body film 27 are joined together by intermolecular force. The surface of the Pt film 26 of the AIN piezoelectric-body film 27 and the PZT piezoelectric-body film 17 are joined together by intermolecular force. For these joints, the use of an adhesive agent is unnecessary. For excellently joining these surfaces by intermolecular force, the surface roughness of a sticking surface of the AIN piezoelectric-body film 27, a sticking surface of the PZT piezoelectric-body film 17, the Pt film 34 and the Pt film 26 is desired to be less than or equal to 10 nm. For this purpose, processes for smoothing the surfaces of the Pt film 34 and the Pt film 26 may be executed. Further, an interface when the sticking surface of the AIN piezoelectric-body film 27 has been stuck on the Pt film 34 is less than or equal to 10 nm. Furthermore, area of the surface of the Pt film 34 is desired to be larger than area of the sticking surface of the AIN piezoelectric-body film 27. Thanks to such structure, a permissible range of a sticking accuracy error when the AIN piezoelectric-body film 27 is stuck on the Pt film 34 can be made wide.

### (1-2) Manufacturing Method

In the manufacture of the piezoelectric-body film joint substrate 100, the AIN piezoelectric-body film 27 formed on a growth substrate 21 and including the AIN film 25 and the Pt film 26 formed on the AIN film 25 and the PZT piezoelectric-body film 17 formed on a growth substrate 11 and including the PZT film 15 and the Pt film 16 formed on the PZT film 15 are peeled off respectively from the growth substrates 21 and 11, the AIN piezoelectric-body film 27 is stuck on the Pt films 34 as the electrode formed on the SOI substrate 33 different from both of the growth substrates 21 and 11, and the PZT piezoelectric-body film 17 is stuck on the AIN piezoelectric-body film 27.

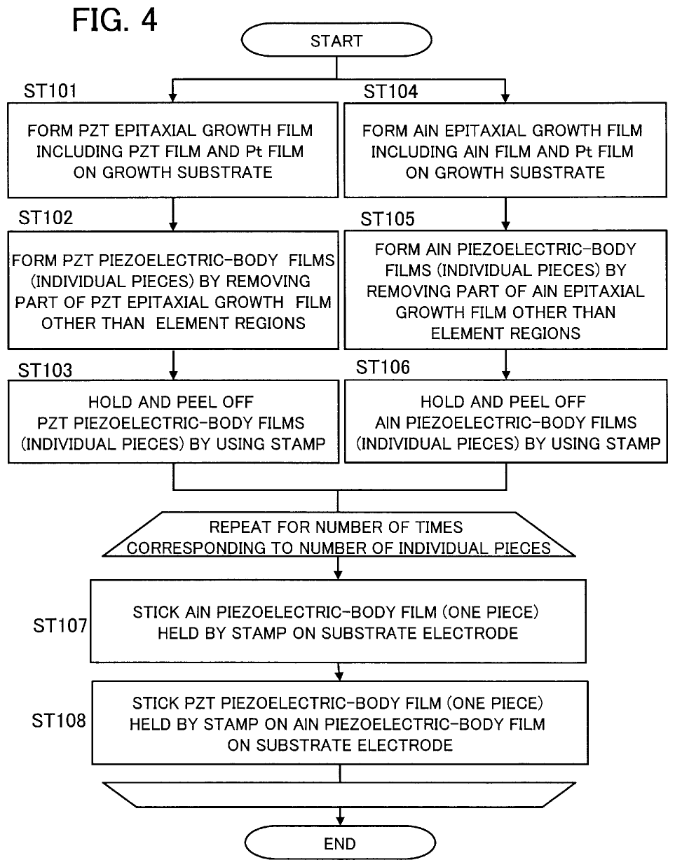

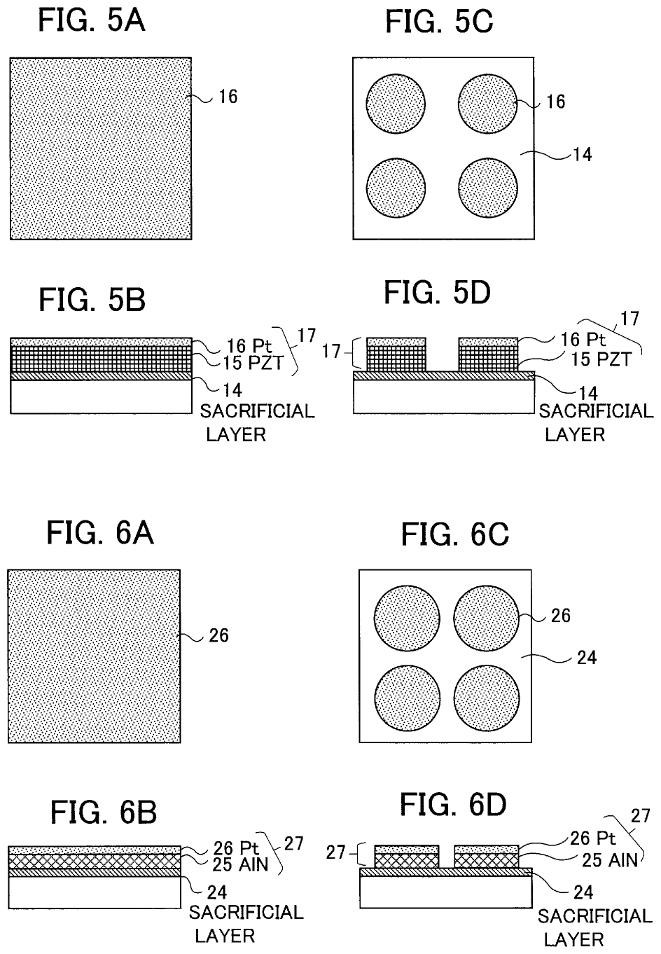

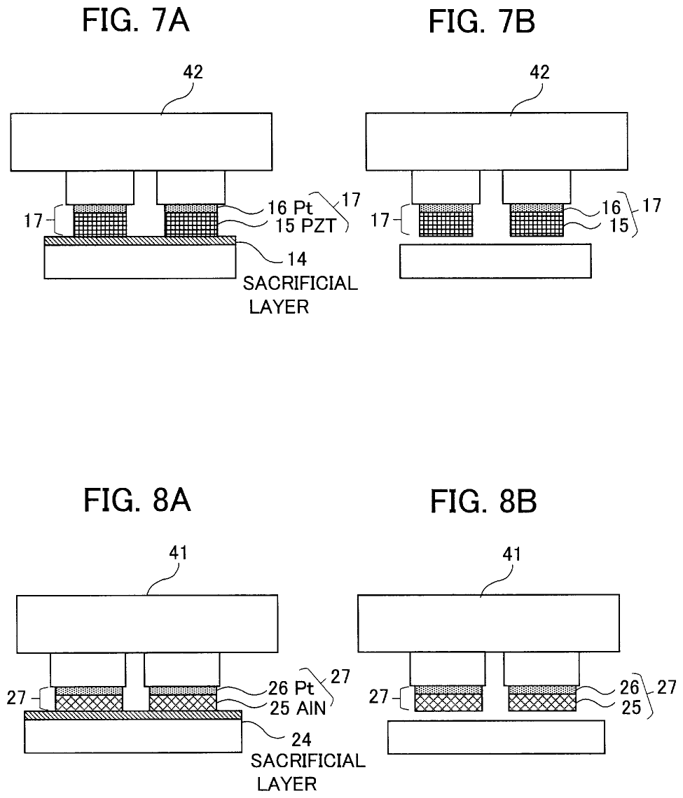

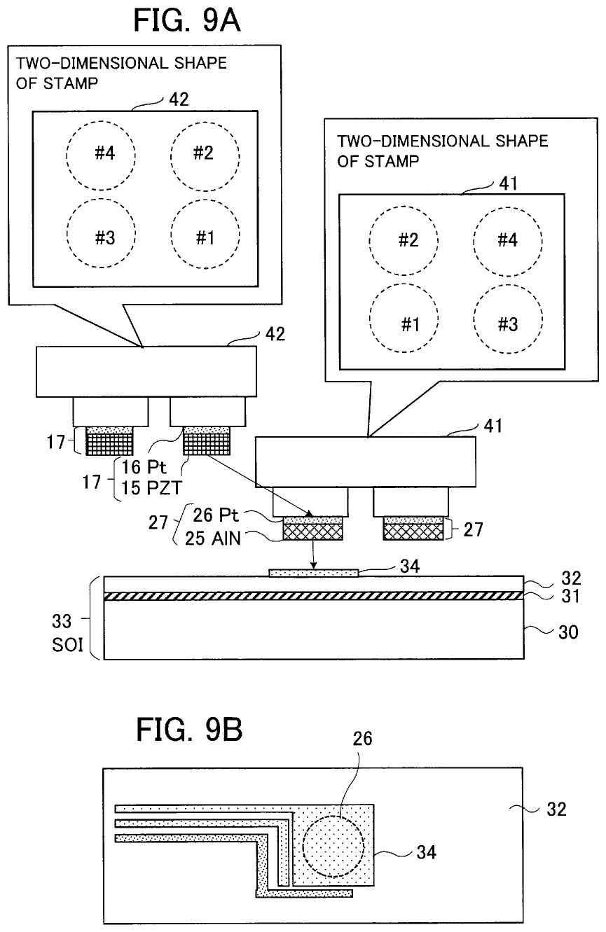

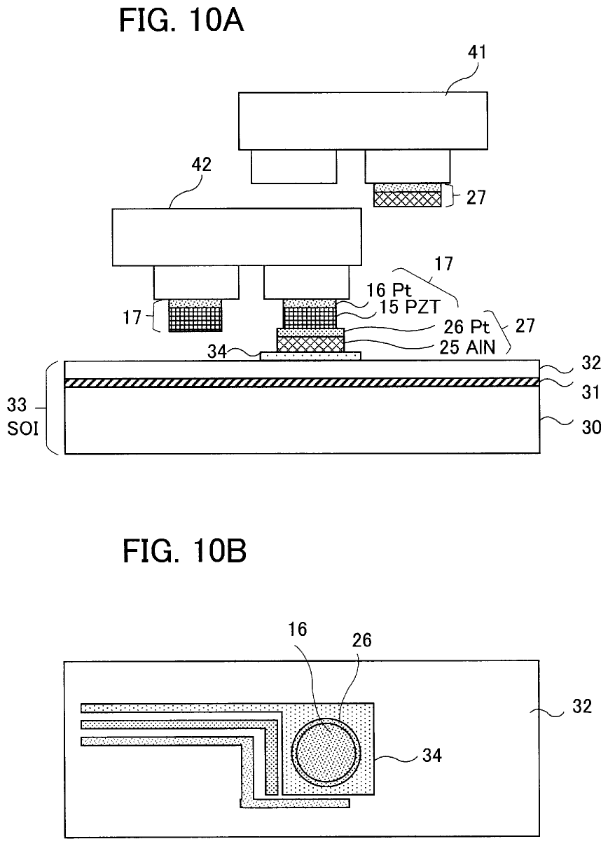

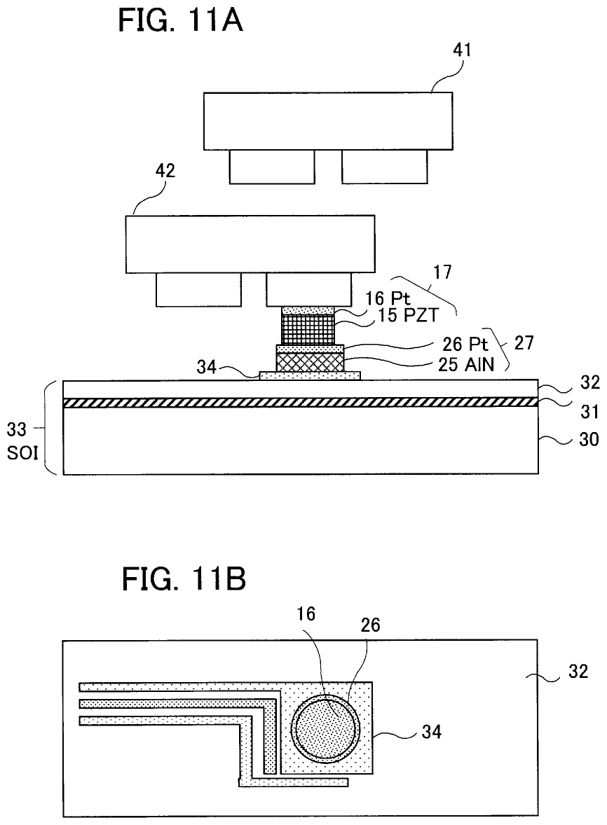

FIG. 4 is a flowchart showing a method of manufacturing the piezoelectric-body film joint substrate 100. FIGS. 5A and 5B are a top view and a cross-sectional view schematically showing the structure of a PZT epitaxial growth film in step ST101 in FIG. 4. FIGS. 5C and 5D are a top view and a cross-sectional view schematically showing the structure of the PZT epitaxial growth film in step ST102 in FIG. 4. FIGS. 6A and 6B are a top view and a cross-sectional view schematically showing the structure of an AIN epitaxial growth film in step ST104 in FIG. 4. FIGS. 6C and 6D are a top view and a cross-sectional view schematically showing the structure of the AIN epitaxial growth film in step ST105 in FIG. 4. FIGS. 7A and 7B are cross-sectional views schematically showing a holding process of a plurality of PZT piezoelectric-body films 17 in step ST103 in FIG. 4. FIGS. 8A and 8B are cross-sectional views schematically showing a holding process of a plurality of AIN piezoelectric-body films 27 in step ST106 in FIG. 4. FIG. 9A is a cross-sectional view schematically showing a sticking process of the AIN piezoelectric-body film 27 in step ST107 in FIG. 4, and FIG. 9B is a top view showing a state in which the AIN piezoelectric-body film 27 has been stuck. FIG. 10A is a cross-sectional view schematically showing a sticking process of the PZT piezoelectric-body film 17 in step ST108 in FIG. 4, and FIG. 10B is a top view showing a state in which the PZT piezoelectric-body film 17 has been stuck. FIG. 11A is a cross-sectional view showing a manufacturing process of the next piezoelectric-body film joint substrate, and FIG. 11B is a top view showing a state in which the PZT piezoelectric-body film 17 has been stuck.

First, a sacrificial layer 14, the PZT film 15 and the Pt film 16 are grown epitaxially on a growth substrate as shown in FIGS. 5A and 5B (step ST101), and a plurality of PZT piezoelectric-body films 17 are formed by forming the PZT film and the Pt film 16 into circular shapes by means of etching as shown in FIGS. 5C and 5D (step ST102).

Further, a sacrificial layer 24, the AIN film 25 and the Pt film 26 are grown epitaxially on another growth substrate as shown in FIGS. 6A and 6B (step ST104), and a plurality of AIN piezoelectric-body films 27 are formed by forming the AIN film and the Pt film 26 into circular shapes by means of etching as shown in FIGS. 6C and 6D (step ST105).

Subsequently, as shown in FIGS. 7A and 7B, the plurality of (4 in the illustrated example) PZT piezoelectric-body films 17 as individual pieces each formed with the PZT film 15 and the Pt film 16 are held by a stamp 42 as a holding member and are peeled off by etching the sacrificial layer (step ST103). Further, as shown in FIGS. 8A and 8B, the plurality of (4 in the illustrated example) AIN piezoelectric-body films 27 as individual pieces each formed with the AIN film 25 and the Pt film 26 are held by a stamp 41 as a holding member and are peeled off by etching the sacrificial layer (step ST106).

Subsequently, as shown in FIGS. 9A and 9B, one of the plurality of AIN piezoelectric-body films 27 held by the stamp 41 is stuck on the Pt film 34 (step ST107).

Subsequently, as shown in FIGS. 10A and 10B, one of the plurality of PZT piezoelectric-body films 17 held by the stamp 42 is stuck on the Pt film 26 of the AIN piezoelectric-body film 27 that has been stuck on the Pt film 34 (step ST108). It is also possible to add a process of strengthening the sticking of Pt and each piezoelectric film by performing an annealing process after the sticking.

As shown in FIGS. 9A and 9B, in the first embodiment, contact electrodes and a wiring pattern are formed with Pt on the SOI substrate 33, the AIN piezoelectric-body film 27 is stuck, and thereafter the PZT piezoelectric-body film 17 is overlaid and stuck on the Pt film 26 as the upper electrode film of the AIN piezoelectric-body film 27. In cases where the AIN piezoelectric-body films 27 held by the stamp 41 are in a 2×2 matrix, the AIN piezoelectric-body films 27 are successively stuck on different SOI substrates 33 in the illustrated order of *1, *2, *3 and *4. In this case, the AIN piezoelectric-body film 27 as the piezoelectric-body film having greater diameter is stuck first. In this example, four SOI substrates 33 are prepared for the four piezoelectric-body films. The PZT piezoelectric-body film 17 is stuck on the AIN piezoelectric-body film 27 as shown in FIGS. 10A and 10B. The sticking is executed successively in the order of *1, *2, *3 and *4, and thus the stamp 42 as the holding member for sticking the PZT piezoelectric-body film 17 on the AIN piezoelectric-body film 27 is capable of executing the sticking without interfering with the AIN piezoelectric-body film 27 as shown in FIG. 11A.

Subsequently, the insulation film 35a and the wiring film 36a are formed on the PZT film 15 and the Pt film 16, and the insulation film 35b and the wiring film 36b are formed on the AIN film 25 and the Pt film 26.

At the time of the sticking, the hexagonal crystal of AIN and the cubic crystal of PZT are arranged in a phase relationship so that their c-axes are parallel to each other, by which efficiency of the piezoelectric oscillation driving of the PZT film 15 and the piezoelectric oscillation reception of the AIN film 25 is maximized.

### (1-3) Modification

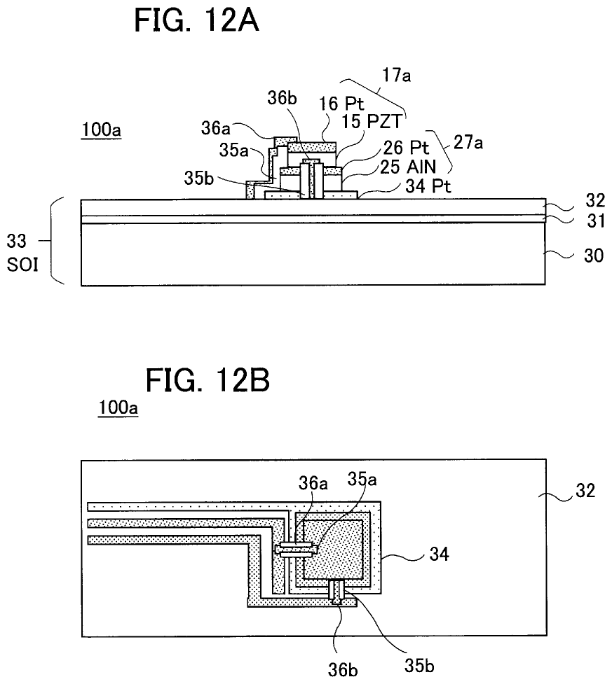

FIGS. 12A and 12B are a side view and a top view schematically showing the structure of a piezoelectric-body film joint substrate 100a according to a modification of the first embodiment. The piezoelectric-body film joint substrate 100a differs from the piezoelectric-body film joint substrate 100 shown in FIG. 1 to FIG. 3 in that the two-dimensional shape of each of an AIN piezoelectric-body film 27a and a PZT piezoelectric-body film 17a is a quadrangular shape. Except for this feature, the piezoelectric-body film joint substrate 100a is the same as the piezoelectric-body film joint substrate 100.

### (1-4) Effect

As described above, in the first embodiment, the PZT piezoelectric-body film 17 and the AIN piezoelectric-body film 27, which are unlikely to grow epitaxially on the same SOI substrate 33 because of the difference in the lattice constant and the crystal structure, are respectively formed on separate growth substrates, peeled off from the growth substrates, and stuck on a common SOI substrate 33 in superimposition with each other, by which a high-performance piezoelectric-body film joint substrate 100 can be made.

Further, since the PZT film 15 being monocrystalline has a higher piezoelectric constant compared to a polycrystalline PZT film, amplitude of the oscillation can be increased with ease. Furthermore, since the AIN film 25 being monocrystalline has lower specific inductive capacity compared to a polycrystalline AIN film, the oscillation reception sensitivity can be increased. However, the PZT film 15 may contain polycrystalline PZT, and the AIN film 25 may contain polycrystalline AIN. Namely, monocrystallization ratios of the PZT film 15 and the AIN film 25 may be less than or equal to 100%.

Furthermore, conventionally, in order to form piezoelectric films of different types, a process like temporarily covering one piezoelectric film with a protective layer, forming the other piezoelectric film, and thereafter removing the protective layer used to be a complicated process, and application of heat in processing in each step used to leave residual stress distortion in the piezoelectric films and cause deterioration in the efficiency of the sensor. By the manufacturing method in the first embodiment, the piezoelectric-body film joint substrate and the acoustic oscillation sensor can be formed in a state with no residual stress distortion.

### (2) Second Embodiment

(2-1) Structure of piezoelectric-body film Joint Substrate 200

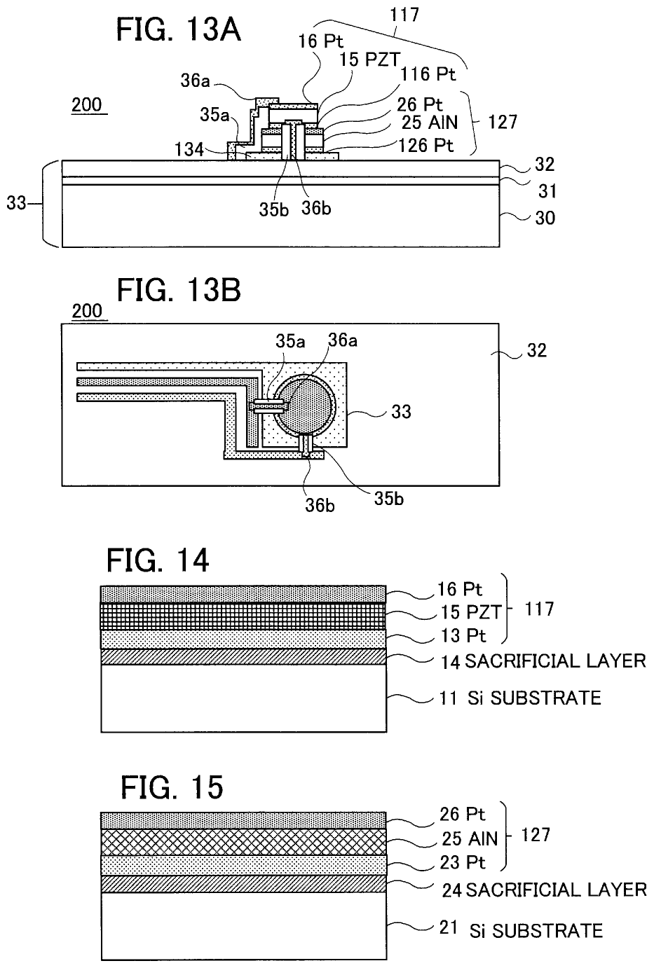

FIGS. 13A and 13B are a side view and a top view schematically showing the structure of a piezoelectric-body film joint substrate 200 according to a second embodiment. In FIGS. 13A and 13B, each component identical or corresponding to a component shown in FIG. 1 to FIG. 3 is assigned the same reference character as in FIG. 1 to FIG. 3.

The piezoelectric-body film joint substrate 200 includes an AIN piezoelectric-body film 127 as a first piezoelectric-body film stuck on a Pt film 134 and a PZT piezoelectric-body film 117 as a second piezoelectric-body film stuck on the AIN piezoelectric-body film 127. The AIN piezoelectric-body film 127 includes a Pt film 126 as a first lower electrode film, the AIN film 25 as a first piezoelectric film formed on the Pt film 126, and the Pt film 26 as a first upper electrode film formed on the AIN film 25. The PZT piezoelectric-body film 117 includes a Pt film 116 as a second lower electrode film, the PZT film 15 as a second piezoelectric film different from the first piezoelectric film (e.g., in crystal structure), and the Pt film 16 as a second upper electrode film formed on the PZT film 15, and the Pt film 116 is stuck on the Pt film 26. Further, area of the PZT piezoelectric-body film 117 and area of the AIN piezoelectric-body film 127 differ from each other. In the second embodiment, the area of the PZT piezoelectric-body film 117 is smaller than the area of the AIN piezoelectric-body film 127. Except for the above-described features, the structure of the piezoelectric-body film joint substrate 200 is the same as that of the piezoelectric-body film joint substrate 100. While the substrate electrode is formed with Pt (platinum) in this example, it is not particularly necessary to limit the material of the substrate electrode to Pt. For example, the substrate electrode may be formed with a variety of metal such as gold, aluminum or copper.

### (2-2) Manufacturing Method

FIG. 14 is a cross-sectional view schematically showing the structure of an epitaxial growth film including the PZT piezoelectric-body film 117. FIG. 15 is a cross-sectional view schematically showing the structure of an epitaxial growth film including the AIN piezoelectric-body film 127. In the manufacture of the piezoelectric-body film joint substrate 200, the AIN piezoelectric-body film 127 as the first piezoelectric-body film formed on the growth substrate 21 and including the Pt film 126, the AIN film 25 and the Pt film 26 and the PZT piezoelectric-body film 117 formed on the growth substrate 11 and including the Pt film 116, the PZT film 15 and the Pt film 16 are peeled off respectively from the growth substrates 21 and 11, the AIN piezoelectric-body film 127 is stuck on the Pt films 134 formed on the SOI substrate 33 different from both of the growth substrates 21 and 11, and the PZT piezoelectric-body film 117 is stuck on the AIN piezoelectric-body film 127.

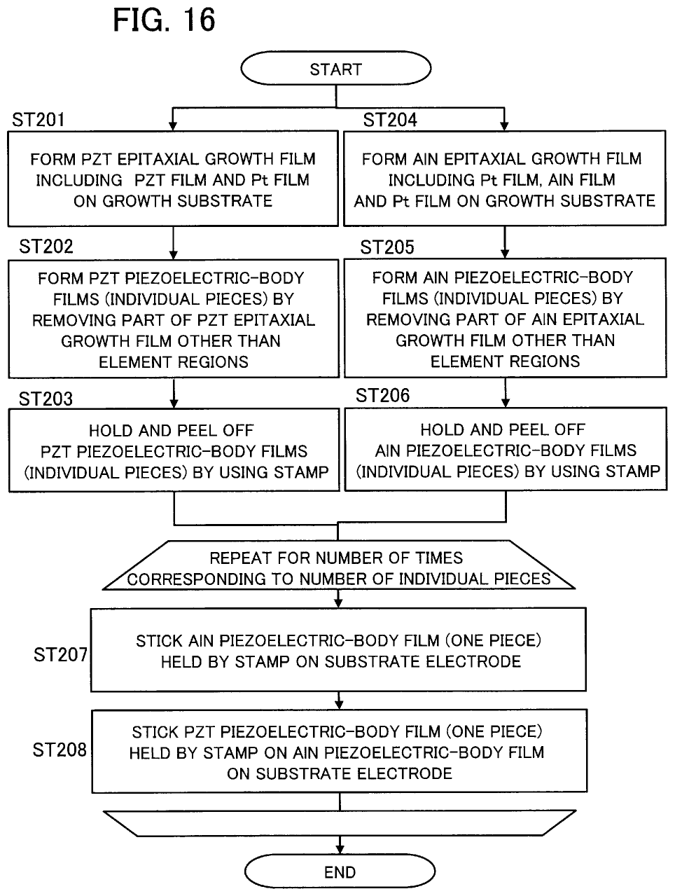

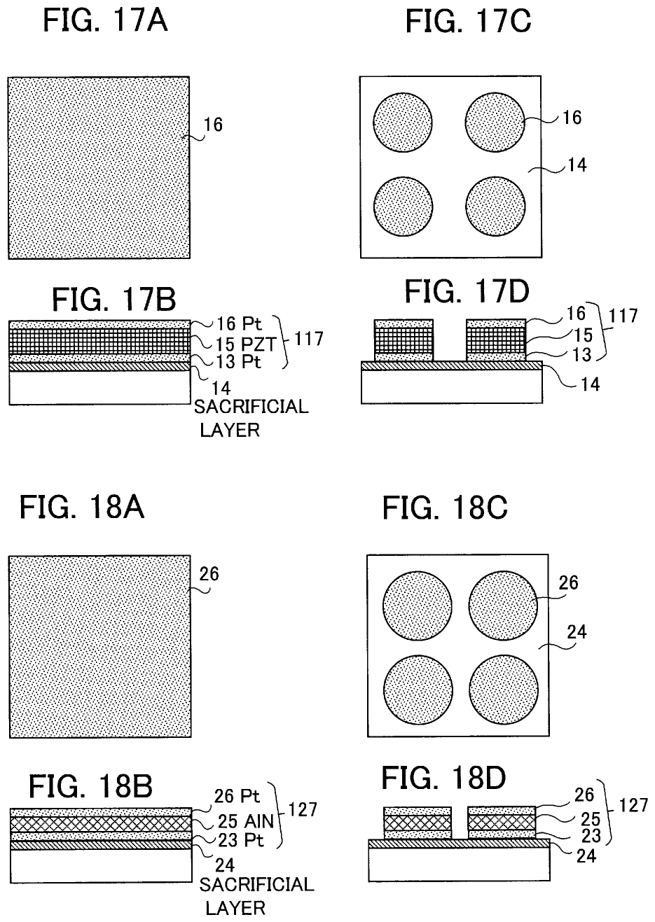

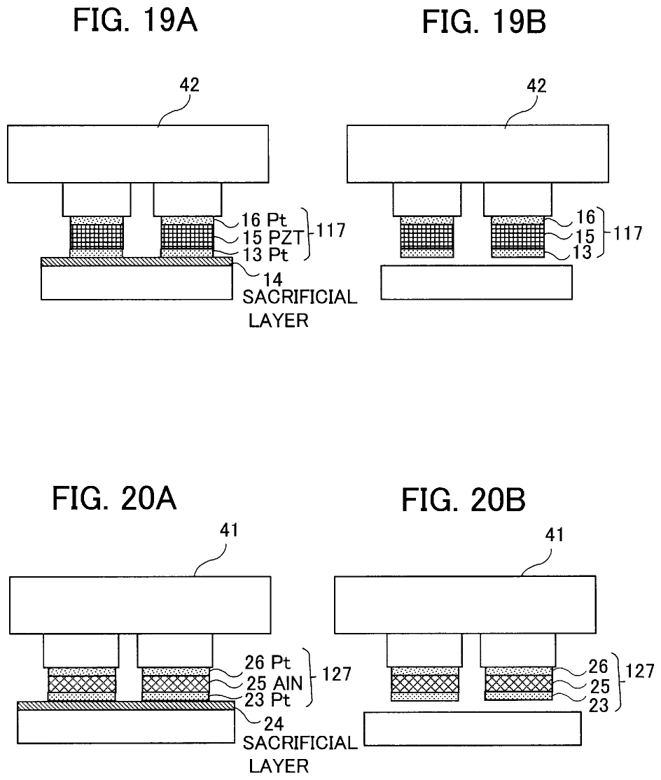

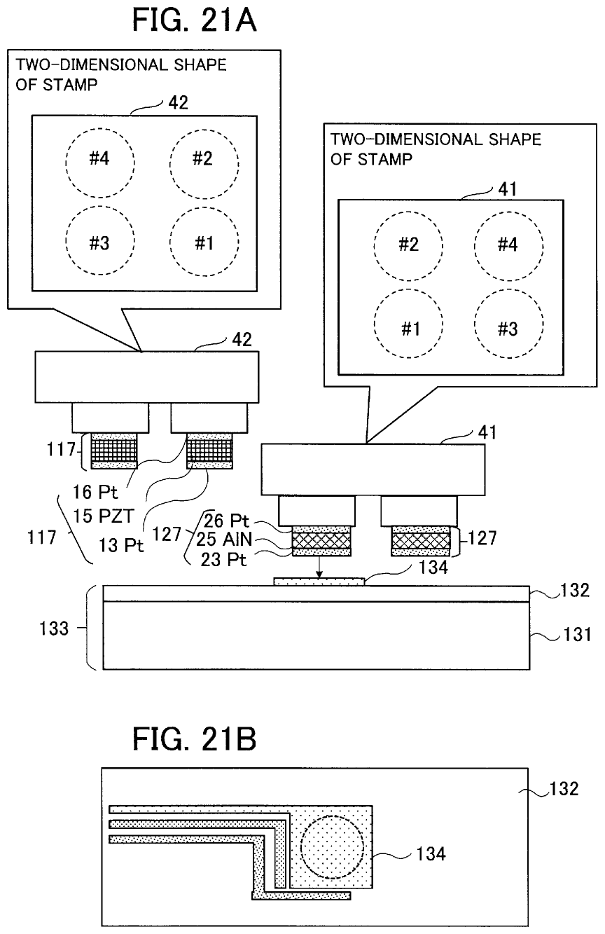

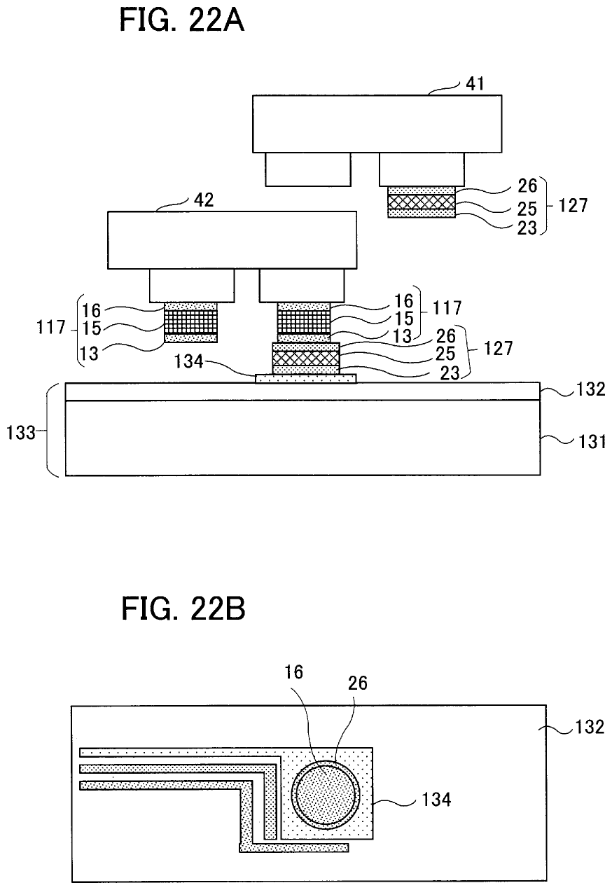

FIG. 16 is a flowchart showing a method of manufacturing the piezoelectric-body film joint substrate 200. FIGS. 17A and 17B are a top view and a cross-sectional view schematically showing the structure of a PZT epitaxial growth film in step ST201 in FIG. 16. FIGS. 17C and 17D are a top view and a cross-sectional view schematically showing the structure of the PZT epitaxial growth film in step ST202 in FIG. 16. FIGS. 18A and 18B are a top view and a cross-sectional view schematically showing the structure of an AIN epitaxial growth film in step ST204 in FIG. 16. FIGS. 18C and 18D are a top view and a cross-sectional view schematically showing the structure of the AIN epitaxial growth film in step ST205 in FIG. 16. FIGS. 19A and 19B are cross-sectional views schematically showing a holding process of a plurality of PZT piezoelectric-body films 117 in step ST203 in FIG. 16. FIGS. 20A and 20B are cross-sectional views schematically showing a holding process of a plurality of AIN piezoelectric-body films 127 in step ST206 in FIG. 16. FIG. 21A is a cross-sectional view schematically showing a sticking process of the AIN piezoelectric-body film 127 in step ST207 in FIG. 16, and FIG. 21B is a top view showing a state in which the AIN piezoelectric-body film 127 has been stuck. FIG. 22A is a cross-sectional view schematically showing a sticking process of the PZT piezoelectric-body film 117 in step ST208 in FIG. 16, and FIG. 22B is a top view showing a state in which the PZT piezoelectric-body film 117 has been stuck.

First, the sacrificial layer 14, a Pt film 13, the PZT film 15 and the Pt film 16 are grown epitaxially on a growth substrate as shown in FIGS. 17A and 17B (step ST201), and a plurality of PZT piezoelectric-body films 117 are formed by forming the Pt film 13, the PZT film 15 and the Pt film 16 into circular shapes by means of etching as shown in FIGS. 17C and 17D (step ST202).

Further, the sacrificial layer 24, a Pt film 23, the AIN film 25 and the Pt film 26 are grown epitaxially on another growth substrate as shown in FIGS. 18A and 18B (step ST204), and a plurality of AIN piezoelectric-body films 127 are formed by forming the Pt film 23, the AIN film 25 and the Pt film 26 into circular shapes by means of etching as shown in FIGS. 18C and 18D (step ST205).

Subsequently, as shown in FIGS. 19A and 19B, the plurality of (4 in the illustrated example) PZT piezoelectric-body films 117 as individual pieces each formed with the Pt film 13, the PZT film 15 and the Pt film 16 are held by the stamp 42 as the holding member and are peeled off by etching the sacrificial layer (step ST203). Further, as shown in FIGS. 20A and 20B, the plurality of (4 in the illustrated example) AIN piezoelectric-body films 127 as individual pieces each formed with the Pt film 23, the AIN film 25 and the Pt film 26 are held by the stamp 41 as the holding member and are peeled off by etching the sacrificial layer (step ST206).

Subsequently, as shown in FIGS. 21A and 21B, one of the plurality of AIN piezoelectric-body films 127 held by the stamp 41 is stuck on the Pt film 134 (step ST207). In the second embodiment, an example in which the Pt film 134 is formed on a glass polyimide multilayer substrate 133 is shown. The glass polyimide multilayer substrate 133 is formed with a glass part 131 and a polyimide part 132 stacked on the glass part 131, and the Pt film 134 is formed on the polyimide part 132.

Subsequently, as shown in FIGS. 22A and 22B, one of the plurality of PZT piezoelectric-body films 117 held by the stamp 42 is stuck on the Pt film 26 of the AIN piezoelectric-body film 127 that has been stuck on the Pt film 134 (step ST208). While it is desirable in the first embodiment to add the process of strengthening the sticking of Pt and each piezoelectric film by performing the annealing process after the sticking, it is unnecessary to perform the annealing process in the second embodiment since each piezoelectric-body film has structure including the Pt film 16, 26 as the upper electrode and the Pt film 13, 23 as the lower electrode.

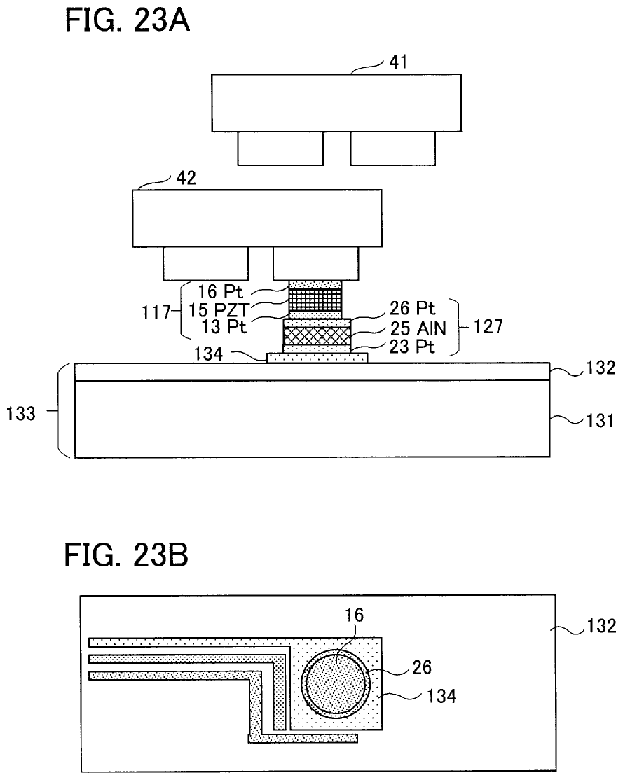

As shown in FIGS. 23A and 23B, in the second embodiment, the contact electrodes and the wiring pattern are formed with Pt on the glass polyimide multilayer substrate 133, the AIN piezoelectric-body film 127 is stuck, and thereafter the PZT piezoelectric-body film 117 is overlaid and stuck on the Pt film 26 as the upper electrode film of the AIN piezoelectric-body film 127. In cases where the AIN piezoelectric-body films 127 held by the stamp 41 are in a 2×2 matrix, the AIN piezoelectric-body films 27 are successively stuck on different glass polyimide multilayer substrates 133 in the illustrated order of *1, *2, *3 and *4. In this case, the AIN piezoelectric-body film 127 as the piezoelectric-body film having greater diameter is stuck first. In this example, four glass polyimide multilayer substrates 133 are prepared for the four piezoelectric-body films. The PZT piezoelectric-body film 117 is stuck on the AIN piezoelectric-body film 127 as shown in FIGS. 22A and 22B. The sticking is executed successively in the order of *1, *2, *3 and *4, and thus the stamp 42 as the holding member for sticking the PZT piezoelectric-body film 117 on the AIN piezoelectric-body film 127 is capable of executing the sticking without interfering with the AIN piezoelectric-body film 127 as shown in FIG. 23A.

Subsequently, the insulation film 35a and the wiring film 36a are formed on the PZT film 15 and the Pt film 16, and the insulation film 35b and the wiring film 36b are formed on the AIN film 25 and the Pt film 26.

### (2-3) Effect

As described above, in the second embodiment, the PZT piezoelectric-body film 117 and the AIN piezoelectric-body film 127, which are unlikely to grow epitaxially on the same glass polyimide multilayer substrate 133, are respectively grown epitaxially on separate growth substrates, peeled off from the growth substrates, and stuck on a common glass polyimide multilayer substrate 133 in superimposition with each other, by which a high-performance piezoelectric-body film joint substrate 200 can be made.

Further, according to the manufacturing method in the second embodiment, the annealing process for stabilizing characteristics is necessary, and thus a plurality of piezoelectric-body films differing in the crystal structure can be provided on a non-heat-resistant substrate.

Incidentally, except for the above-described features, the second embodiment is the same as the first embodiment.

### (3) Description of Reference Characters

100, 100a, 200: piezoelectric-body film joint substrate, 11, 21: growth substrate (monocrystalline Si substrate), 15: PZT film (second piezoelectric film), 16: Pt film (second upper electrode film), 13: Pt film (second lower electrode film), 14, 24: sacrificial layer, 17, 117: PZT piezoelectric-body film (second piezoelectric-body film), 23: Pt film (first lower electrode film), 25: AIN film (first piezoelectric film), 26: Pt film (first upper electrode film), 27, 127: AIN piezoelectric-body film (first piezoelectric-body film), 31: SiO₂ part, 32: monocrystalline Si part, 33: SOI substrate (substrate), 34, 134: Pt film (substrate electrode), 116: Pt film, 126: Pt film, 133: glass polyimide multilayer substrate.

What is claimed is:

1. A piezoelectric-body film joint substrate comprising:
a substrate;
a substrate electrode provided on the substrate;
a first piezoelectric-body film stuck on the substrate electrode and including a first piezoelectric film and a first upper electrode film formed on the first piezoelectric film; and
a second piezoelectric-body film stuck on the first upper electrode film and including a second piezoelectric film different from the first piezoelectric film and a second upper electrode film formed on the second piezoelectric film.

2. The piezoelectric-body film joint substrate according to claim 1, wherein area of the first piezoelectric-body film and area of the second piezoelectric-body film differ from each other.

3. The piezoelectric-body film joint substrate according to claim 1, wherein the area of the second piezoelectric-body film is smaller than the area of the first piezoelectric-body film.

4. The piezoelectric-body film joint substrate according to claim 1, wherein the second piezoelectric-body film further includes a second lower electrode film formed on a surface of the second piezoelectric film on a side opposite to the second upper electrode film.

5. The piezoelectric-body film joint substrate according to claim 1, wherein the first piezoelectric-body film further includes a first lower electrode film formed on a surface of the first piezoelectric film on a side opposite to the first upper electrode film.

6. The piezoelectric-body film joint substrate according to claim 1, wherein the second piezoelectric film is monocrystalline and the first piezoelectric film is monocrystalline.

7. The piezoelectric-body film joint substrate according to claim 1, wherein area of a surface of the substrate electrode is larger than area of a sticking surface of the first piezoelectric-body film stuck on the surface of the substrate electrode.

8. The piezoelectric-body film joint substrate according to claim 1, wherein
the first piezoelectric film is an AIN film, a lithium tantalate film or a lithium niobate film, and
the second piezoelectric film is a PZT film, a KNN film or a barium titanate film.

9. A method of manufacturing a piezoelectric-body film joint substrate, the method comprising:
peeling off a first piezoelectric-body film formed on a first substrate and including a first piezoelectric film and a first electrode film provided on the first piezoelectric film and a second piezoelectric-body film formed on a second substrate and including a second piezoelectric film and a second electrode film provided on the second piezoelectric film respectively from the first substrate and the second substrate;
sticking the first piezoelectric-body film on an electrode formed on a third substrate different from both of the first substrate and the second substrate; and
sticking the second piezoelectric-body film on the first piezoelectric-body film.

10. The method of manufacturing a piezoelectric-body film joint substrate according to claim 9, wherein the second piezoelectric-body film further includes a second lower electrode film formed on a surface of the second piezoelectric film on a side opposite to the second electrode film.

11. The method of manufacturing a piezoelectric-body film joint substrate according to claim 9, wherein the first piezoelectric-body film further includes a first lower electrode film formed on a surface of the first piezoelectric film on a side opposite to the first electrode film.

12. The method of manufacturing a piezoelectric-body film joint substrate according to claim 9, wherein the second piezoelectric film is monocrystalline and the first piezoelectric film is monocrystalline.

13. The method of manufacturing a piezoelectric-body film joint substrate according to claim 9, wherein area of a surface of the electrode formed on the third substrate is larger than area of a sticking surface of the first piezoelectric-body film to be stuck on the surface of the electrode.
